(19) United States
(12) Patent Application Publication
(10) Pub. No.: US 2002/0044021 A1
(43) Pub. Date: Apr. 18, 2002

(54) Filter arrangement

(76) Inventors: Wim Van Der Woude, Son (NL); Leonardus Ruitenburg, Swalmen (NL)

Correspondence Address: Jack E. Haken, U.S. Philips Corporation, 580 White Plains Road, Tarrytown, NY, 10591, US

(21) Appl. No.: 09/862,283

(22) Filed: May 22, 2001

(30) Foreign Application Priority Data
May 26, 2000 (DE) 10026161.2

(51) Int. Cl. H03B 1/00

(52) U.S. Cl. 331/74

(57) ABSTRACT

The invention relates to a filter arrangement having a local oscillator (4), having two band-pass filters (1, 2) and having a mixer (3). The novel filter arrangement distinguishes itself in that two band-pass filters (1, 2) having the same bandwidth f_{B} and center frequency f_{c} have been provided, the first band-pass filter (1) having its output coupled to the input of the second band-pass filter (2) by means of a mixer (3), and the local oscillator (4) is adapted to control the mixer (3).

The present invention relates to a filter arrangement having a local oscillator, having band-pass filters and having a mixer.

From the document WO 95/12953 a satellite receiver is known, which includes a filter arrangement for varying the bandwidth during the preselection of the receiving signal. The filter arrangement includes, inter alia, two band-pass filters, two mixers and two local oscillators.

It is an object of the present invention to provide a filter arrangement with a variable bandwidth and variable center frequency of the output signal, which requires a minimal number of cheap circuit elements.

According to the invention the object is achieved in that two band-pass filters having the same bandwidth and center frequency have been provided, the first band-pass filter having its output coupled to the input of the second band-pass filter by means of a mixer, and the local oscillator is adapted to control the mixer. This arrangement features a particularly simple design because it requires only one mixer and two similar band-pass filters.

The embodiments as defined in claim 2 enable the characteristics of the coupled band-pass filters and, consequently, of the entire filter arrangement to be changed. Since the local oscillator supplies an output signal of variably adjustable frequency the bandwidth and the center frequency of the output signal of the entire filter arrangement can be defined by simply changing the frequency of the output signal of the local oscillator.

In the embodiment as defined in claim 3 the advantages of the filter arrangement utilized for quadrature amplitude modulation (QAM). Owing to the variable center frequency of the output signal of the filter arrangement this arrangement is very suitable for varying the center frequency, particularly in the case of narrow-band QAM.

The embodiment as defined in claim 4 provides a particularly cheap design of the filter arrangement because both filters are identical and, in addition, have a fixed invariable bandwidth.

An embodiment of the invention will be described in more detail hereinafter by way of example with respect to two Figures of drawing. In the drawings:

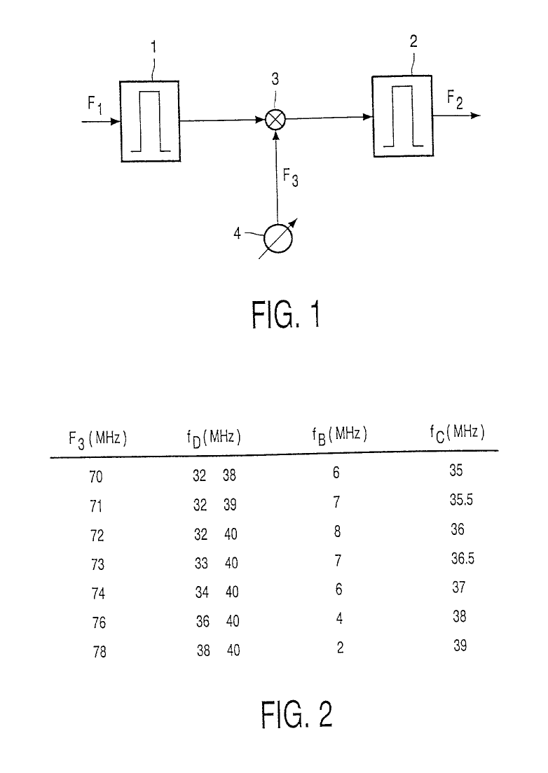

FIG. 1 shows the structure of the filter arrangement in accordance with the invention, and

FIG. 2 shows a frequency table for the filter arrangement in accordance with the invention.

The elements of the filter arrangement shown in FIG. 1 are a first band-pass filter 1, a second band-pass filter 2, a mixer 3 and a local oscillator 4. This filter arrangement receives an input signal F₁ and supplies an output signal F₂. The arrangement serves to vary the bandwidth f_{B} and the center frequency f_{c} of the output signal F₂. For this purpose, the input signal F₁ is applied to the first band-pass filter 1, which has its output connected to the input of the second band-pass filter 2 via the mixer 3. The mixer 3 is then supplied with the output signal F₃ of the local oscillator 4 with a variable frequency. When the frequency of the local oscillator 4 varies and the parameters of the two band-pass filters 1, 2 are left unchanged, the center frequency f_{c} of the output signal F₂ will vary. However, this also causes the bandwidth f_{B} of the output signal F₂ to be changed at the same time. In order to use as many standard elements as possible, the two band-pass filters 1, 2 are identical and have a fixed bandwidth f_{B}. This results in a particularly cheap design of the entire filter arrangement.

FIG. 2 shows how the bandwidth and the center frequency change when the applied frequency of the oscillator 4 is varied. The frequency of the output signal F₃ of the local oscillator 4 is then varied between 70 MHz and 78 MHz. The cut-off frequencies f_{D} of the two band-pass filters 1, 2 lie between 32 MHz and 40 MHz. This yields bandwidths f_{B} of the output signal F₂ from 2 MHz to 8 MHz. The center frequencies f_{c} lie between 35 MHz and 39 MHz.

This filter arrangement of simple design is also suitable for the tuning of the intermediate frequency in the case of quadrature amplitude modulation (QAM) if the mixer has a satisfactory noise immunity. Thus, QAM, which is used for example in tuners and settop boxes for difference television, can be realized with a small number of parts at low cost, which is a major advantage in the case of production in large quantities.

1. A filter arrangement having a local oscillator(4), having band-pass filters (1, 2) and having a mixer (3),
characterized in that
two band-pass filters (1, 2) having the same bandwidth f_{B} and center frequency f_{c} have been provided, the first band-pass filter (1) having its output coupled to the input of the second band-pass filter (2) by means of a mixer (3), and the local oscillator (4) is adapted to control the mixer (3).

2. A filter arrangement as claimed in claim 1,
characterized in that
the frequency of the output signal (F₃) of the local oscillator (4) is variable and the bandwidth f_{B} and the center frequency f_{c} of the output signal (F₂) of the filter arrangement is varied by changing the frequency of the output signal (F₃) of the local oscillator (4).

3. A filter arrangement as claimed in claim 2,
characterized in that
it is adapted to select the intermediate frequency in the case of quadrature amplitude modulation.

4. A filter arrangement as claimed in claim 1,
characterized in that
the band-pass filters (1, 2) have a fixed bandwidth f_{B}.
